(19) United States
(12) Patent Application Publication
(10) Pub. No.: US 2025/0334639 A1
(43) Pub. Date: Oct. 30, 2025

(54) ESTIMATING A STATE OF ENERGY OF A BATTERY

(71) Applicants: SAFRAN ELECTRICAL & POWER, BLAGNAC (FR); UNIVERSITE DE TECHNOLOGIE DE COMPIEGNE, COMPIEGNE (FR); CENTRE NATIONAL DE LA RECHERCHE SCIENTIFIQUE, Paris (FR)

(72) Inventors: Fernanda VENDRAME, MOISSY-CRAMAYEL (FR); Christophe FORGEZ, COMPIEGNE (FR)

(73) Assignees: SAFRAN ELECTRICAL & POWER, BLAGNAC (FR); UNIVERSITE DE TECHNOLOGIE DE COMPIEGNE, COMPIEGNE (FR); CENTRE NATIONAL DE LA RECHERCHE SCIENTIFIQUE (CNRS), Paris (FR)

(21) Appl. No.: 18/866,883

(22) PCT Filed: May 17, 2023
(86) PCT No.: PCT/FR2023/050706

§ 371 Date: Nov. 18, 2024

(30) Foreign Application Priority Data
May 20, 2022 (FR) FR2204853

(51) Int. Cl. G01R 31/374; G01R 31/367; G01R 31/3842; G01R 31/389; G01R 31/396; H01M 10/48

(52) U.S. Cl. CPC G01R 31/374; G01R 31/367; G01R 31/3842; G01R 31/389; G01R 31/396; H01M 10/486; H01M 2220/20

(57) ABSTRACT

Estimating the state of energy for a particular time, which includes:

receiving measurements of a temperature of the cell, of a voltage of the cell, and of a current exchanged by the cell;

estimating an internal resistance of the cell;

estimating an open circuit voltage of the cell;

estimating a total energy delivered by the cell until the particular time;

estimating a maximum energy that can be delivered by the cell, assuming that the temperature and the current remain constant; and

subtracting the estimated total delivered energy from the estimated maximum energy.

### TECHNICAL FIELD OF THE INVENTION

The present invention relates to a method for estimating a state of energy of a cell of a battery, and to an associated computer program, device and aircraft.

### TECHNICAL BACKGROUND

The State Of Energy (SOE) of a battery cell indicates the amount of energy available in the cell. This concept is therefore different from the total stored energy, since a portion of the total stored energy may not be usable and therefore available.

The SOE may be expressed as an absolute value (Wh) or relative to the maximum energy that the battery may hold (%). The SOE is not a measurable quantity, so it must be estimated from measurements available on the cell: current exchanged across the terminals of the cell, voltage at the terminals of the cell and temperature of the cell.

To do this, it is known to use a neural network to give the SOE at a given instant based on the current, voltage and temperature at that instant.

However, such a neural network is not a deterministic system. It is very difficult to obtain a certification in the aeronautical field, particularly in a hybrid or fully electric aircraft, when the battery is used by the propulsion system.

The purpose of the invention is therefore to provide an alternative method for estimating a state of energy of a cell of a battery, for which a certification may be obtained.

### SUMMARY OF THE INVENTION

A method is therefore proposed for estimating a state of energy of a cell of a battery for a given instant, the cell having two terminals, characterized in that it comprises:
receiving measurements for the given instant of a temperature of the cell, a voltage at the terminals of the cell and a current exchanged by the cell across its terminals;
estimating an internal resistance of the cell for the given instant;
estimating an open circuit voltage of the cell for the given instant from the measured voltage and current, and from the estimated internal resistance, for example by adding to the measured voltage a voltage of the internal resistance resulting from a passage of the measured current through the internal resistance;
estimating a total energy delivered by the cell up to the given instant, from the measured temperature and current, and from the estimated open circuit voltage, using predefined associations between values of total energy delivered by the cell and values of temperature, current and open circuit voltage;
estimating a maximum energy that may be delivered by the cell, using the predefined associations and assuming that the temperature and the current remain constant at their measurements for the given instant; and
estimating the state of energy of the cell for the given instant, by subtracting the estimated total delivered energy from the estimated maximum energy.

The invention may further comprise one or more of the following additional characteristics, in any technically possible combination.

Advantageously, the internal resistance is estimated for the given instant on the basis of a volt-amperometry measurement.

Advantageously also, the estimation of the internal resistance at the given instant comprises:
a prior estimation of the internal resistance for the given instant from the temperature and current measured at the given instant, using predefined associations between values of the internal resistance and values of temperature and current;
a correction of the prior estimation by multiplying it by a correction ratio between:
   an estimation of the internal resistance at a previous instant by a volt-amperometry measurement, and
   an estimation of the internal resistance at the previous instant from the temperature and current measured at the previous instant, using the predefined associations between values of the internal resistance and values of temperature and current.

Advantageously also, the estimation of the internal resistance at a given instant is carried out independently of the state of charge of the cell.

Advantageously also, the predefined associations between values of total energy delivered by the cell and values of temperature, current and open circuit voltage are in the form of a table.

Advantageously also, the table also gives the total energy delivered as a function of the open circuit voltage, at constant temperature and current, for several combinations of temperature and current.

Advantageously also, the maximum energy is the total energy delivered for a minimum open circuit voltage provided by the predefined associations, at the temperature and current measured at the given instant.

Also proposed is a computer program that may be downloaded from a communications network and/or recorded on a computer-readable medium, characterized in that it comprises instructions for executing the steps of a method according to the invention, when said program is executed on a computer.

A device is also proposed for estimating a state of energy of a cell of a battery for a given instant, the cell having two terminals between which an electrical system is connected, characterized in that it comprises:
a module for receiving, for the given instant, measurements of a temperature of the cell, a voltage at the terminals of the cell and a current exchanged by the cell across its terminals;
a module for estimating an internal resistance of the cell for the given instant;
a module for estimating an open circuit voltage of the cell for the given instant from the measured voltage and current and from the estimated internal resistance, for example by adding to the measured voltage a voltage of the internal resistance resulting from a passage of the measured current through the internal resistance;
a module for estimating a total energy delivered by the cell from the measured temperature and current, and from the estimated open circuit voltage, using predefined associations between values of total energy delivered by the cell and values of temperature, current and open circuit voltage; and
a module for estimating the maximum energy that may be delivered by the cell, assuming that the temperature and the current remain constant at their measurements for the given instant; and
a module for estimating the state of energy of the cell for the given instant, by subtracting the estimated total delivered energy from the estimated maximum energy.

It is also proposed an aircraft comprising:
a battery comprising at least one cell with two terminals;
a sensor for measuring a temperature of the cell;
a sensor for measuring a current exchanged by the cell across its terminals;
a sensor for measuring a voltage between the terminals of the cell; and
a device for estimating the state of energy of the cell, according to the invention.

### BRIEF DESCRIPTION OF THE FIGURES

The invention will be better understood with the aid of the following description, given only by way of example and made with reference to the attached drawings wherein:

FIG. 1 is a functional view of an aircraft wherein the invention is implemented,

FIG. 2 is a functional view of modules of a computer program of a device for estimating a state of energy of a cell of a battery of the aircraft of FIG. 1,

FIG. 3 is a graph illustrating the evolution of a total energy delivered by the cell as a function of an open circuit voltage of this cell, for several combinations of temperature and current exchanged by the battery,

FIG. 4 is an electrical diagram of a model of the cell of the battery,

FIG. 5 is a block diagram of a method for calculating associations between the total energy and the open circuit voltage, for several combinations of temperature and current, based on the model in FIG. 4, and

FIG. 6 is a block diagram of a method for estimating a state of energy of the battery.

### DETAILED DESCRIPTION OF THE INVENTION

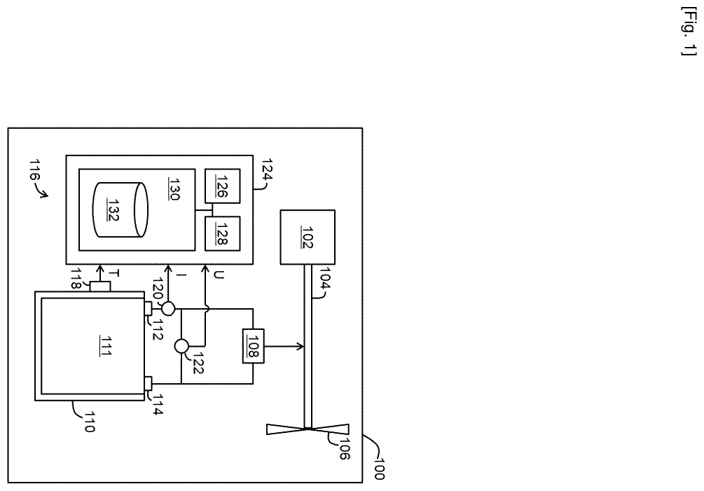

With reference to FIG. 1, an example of an aircraft 100 wherein the invention is implemented will now be described.

The aircraft 100 firstly comprises a turbomachine 102 with an output shaft 104.

The aircraft 100 also comprises a fan 106 designed to propel the aircraft 100. In particular, the fan 106 is connected to the output shaft 104 of the turbomachine 102 so that it may be driven by the latter.

The aircraft 100 also comprises an electrical machine 108 designed, for example, to operate as an electric motor to drive the output shaft 104, instead of or in addition to the turbomachine 102. Alternatively or additionally, the electrical machine 108 is designed to operate as a generator to supply electrical energy from the rotation of the output shaft 104.

The aircraft 100 also comprises a battery 110 comprising at least one cell 111. In the example described, a single cell 111 is provided. The cell 111 has two terminals 112, 114 between which an electrical system is connected. The electrical system is designed to selectively act as an electrical load and be supplied electrically by the battery 110 and act as an electrical source for recharging the battery 110. Alternatively, the electrical system may always act as an electrical load or always as an electrical source. The electrical system comprises, for example, the electrical machine 108.

The aircraft 100 also comprises a system 116 for monitoring the cell 111.

The monitoring system 116 firstly comprises a sensor 118 for measuring the temperature T of the cell 111.

The monitoring system 116 also comprises a sensor 120 for a current I exchanged (i.e. supplied or received) by the cell 111 via its terminals 112, 114.

The monitoring system 116 also comprises a sensor 122 for detecting a voltage U between the terminals 112, 114 of the cell 111.

The sensors 118, 120, 122 are designed to provide measurements of temperature T, current and voltage U respectively, these measurements being either direct or indirect by deduction from one or more other physical quantities.

The monitoring system 116 also comprises a device 124 for monitoring the cell 111. The monitoring device 124 is designed in particular to estimate a state of charge (SOC) of the cell 111, on the basis of the temperature T, the current I and the voltage U, measured by the sensors 118, 120, 122 respectively.

In the example described, the data processing device 124 is a computing system comprising a data processing unit 126 (such as a microprocessor) and a main memory 128 (such as a RAM, acronym for Random Access Memory) accessible by the data processing unit 126. The computing system also comprises, for example, a network interface and/or a computer-readable medium, such as a local medium (such as a local hard disk 130) or a remote medium (such as a remote hard disk accessible via the network interface through a communication network) or a removable medium (such as a Universal Serial Bus (USB) key, or a Compact Disc (CD) or a Digital Versatile Disc (DVD)) that may be read by means of an appropriate computer system drive (such as a USB port or a CD and/or DVD disk drive). A computer program 132 containing instructions for the data processing unit 126 is stored on the medium 130 and/or may be downloaded via the network interface. This computer program 132 is, for example, configured to be loaded into the main memory 128, so that the data processing unit 126 may execute its instructions. To make it easier to describe the computer program 132, the instructions will be described hereafter as organized into software modules. However, this presentation does not prejudge the form of the computer program, which may be of any kind.

Alternatively, all or some of these modules could be implemented in the form of hardware modules, i.e. in the form of an electronic circuit, for example micro-wired, not involving a computer program.

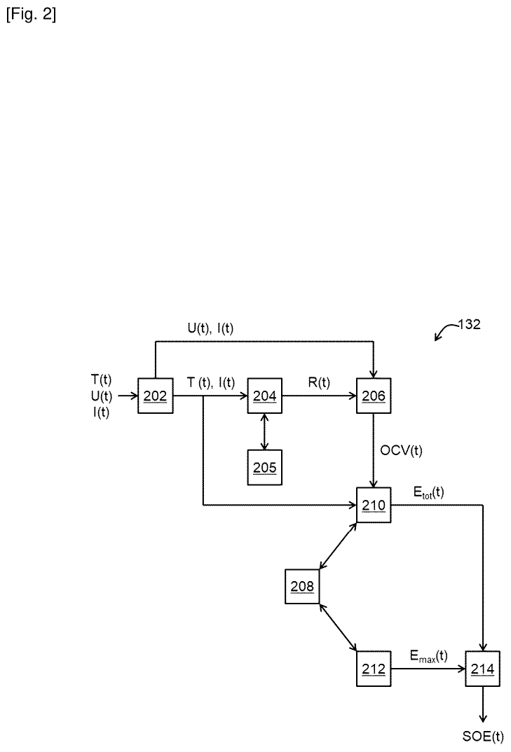

With reference to FIG. 2, an example of embodiment of the computer program 132 will now be described.

The computer program 132 firstly comprises a module 202 designed to receive, from the sensors 118, 120, 122, measurements T(t), U(t), I(t) for the instant t of the temperature T, the voltage U and the current I respectively. For example, these measurements T(t), U(t), I(t) are acquired at the instant t. Alternatively, one or more of these measurements could be acquired prior to the instant t and reused for the instant t.

The computer program 132 also comprises a module 204 designed to estimate an internal resistance R of the cell 111 for the instant t, for example from the measurement T (t) of the temperature T and the measurement I(t) of the current I, preferably independently of a state of charge (SOC) of the cell 111.

Preferably, the module 204 is designed, for at least certain instants t, to estimate the internal resistance R by a volt-amperometric measurement, for example by dividing a variation in the measured voltage U by a variation in the measured current I:

$$R ( t ) = Δ U ( t ) / Δ I ( t ) \qquad [ Math . 1 ]$$

For example, the computer program 132 may comprise a table 205 associating values of the internal resistance R with values of the temperature T and the current I, for example for a predefined and arbitrary state of charge SOC of the cell 111, for example 50%. The table 205 takes the form, for example (the current I is expressed as the nominal current of the cell, noted C for “current rate”):

TABLE 1

| R (Ω) | T (° C.) | I (C) |
|---|---|---|
| 0.1 | 25 | 1 |
| . . . | . . . | . . . |

The module 204 may then be designed to calculate a correction ratio K between the estimation R(t) of the resistance R and another estimation R_{table}(t) obtained using the table 205 from the measurement T(t) of the temperature T and the measurement I(t) of the current I, for example by interpolation:

$$K = R ( t ) / {R}_{table} ( t ) \qquad [ Math . 2 ]$$

In this case, for other instants t, the module 204 is designed, for example, to make a prior estimation R_{table}(t) of the internal resistance R for the given instant t from the measurement T(t) of the temperature T and the measurement I(t) of the current I, using the table 205. For example, the module 204 is designed to determine the prior estimation R_{table}(t) by interpolation. The module 204 may then be designed to correct the prior estimation R_{table}(t) by multiplying it by the ratio K previously obtained as explained above:

$$R ( t ) = K \cdot {R}_{table} ( t ) \qquad [ Math . 3 ]$$

It will be appreciated that the estimations of the internal resistance R from the table 205 are thus made on the assumption that the state of charge SOC of the cell 111 is at a predefined and arbitrary value, even if the actual state of charge of the cell 111 at the instant in question is different.

Alternatively, the associations could take the form, instead of the table 205, of a formula relating the internal resistance R to the temperature T and the current I.

Because the internal resistance R is measured at least at certain instants, it is possible to take rapid account of the unpredictable change in the internal resistance R over time, resulting from the ageing of the cell 111, and therefore from the way wherein the battery 110 is used. This rapid consideration would not be possible with a neural network, which is a “black box” that does not comprise a modifiable parameter representative of the internal resistance. At best, the neural network should be retrained during use, but this would take time and would not allow changes in the internal resistance R to be monitored. The computer program 132 further comprises a module 206 designed to estimate

an open circuit voltage OCV of the cell 111 for the instant t, from the measurement U(t) of the voltage U, the measurement I(t) of the current I and the estimation R(t) of the internal resistance R. In particular, the module 206 is designed to add, to the measurement U(t) of the voltage U, a voltage of the internal resistance R resulting from the passage of the current I through this internal resistance R:

$$OCV ( t ) = U ( t ) + R ( t ) \cdot I ( t ) \qquad [ Math . 4 ]$$

where OCV(t) is the estimation of the open circuit voltage OCV at the instant (t).

The computer program 132 also comprises, for example, a table 208 associating values of a total energy Eₜₒₜ delivered by the cell 111, with values of the temperature T, values of the current I and values of the open circuit voltage OCV. Preferably, the table gives the total delivered energy Eₜₒₜ as a function of the open circuit voltage OCV, at constant temperature T and current I, for several combinations of temperature T and current I. The table 208 takes the form, for example, of:

TABLE 2

| Eₜₒₜ (Wh) | OCV (V) | T (° C.) | I (C) |
|---|---|---|---|
| NA | 3.12 | 0 | 1 |
| 8.724 | 3.13 | 0 | 1 |
| . . . | . . . | . . . | . . . |
| 0.082 | 4.15 | 0 | 1 |
| NA | 4.16 | 0 | 1 |
| NA | 3.08 | 10 | 1 |
| 9.023 | 3.09 | 10 | 1 |
| . . . | . . . | . . . | . . . |
| 0.185 | 4.15 | 10 | 1 |
| NA | 4.16 | 10 | 1 |

. . .

According to the table above, the minimum open circuit voltage OCV at a temperature T of 0° C. and a current I of 1C is 3.13 V and is associated with a total delivered energy Eₜₒₜ (corresponding therefore to the maximum energy Eₘₐₓ that may be delivered) of 8.724 J, since no energy is associated (box “NA”) with the previous value (3.12 V) of open circuit voltage OCV.

Alternatively, the associations could take the form, instead of the table 208, of a formula relating the total delivered energy Eₜₒₜ to the temperature T, the current I and the open circuit voltage OCV.

The computer program 132 further comprises a module 210 designed to estimate the total energy Eₜₒₜ(t) delivered by the cell 111 up to the instant t, from the measurement T(t) of the temperature T, the measurement I(t) of the current I and the estimation OCV(t) of the open circuit voltage OCV, using the table 208. For example, the module 210 is designed to estimate the total energy Eₜₒₜ(t) by interpolation.

The computer program 132 also comprises a module 212 designed to estimate, for the instant t, a maximum energy Eₘₐₓ(t) that may be delivered by the cell 111, assuming that the temperature T and the current I remain constant at their measurements T(t), I(t) for the instant t. For example, the module 212 is designed to use the table 208. In fact, for each combination of temperature T and current I, the open circuit voltage OCV decreases while the total energy delivered Eₜₒₜ increases, up to a minimum value below which the cell 111 is no longer capable of supplying electrical energy. So the maximum energy Eₘₐₓ is the total energy delivered Eₜₒₜ for the minimum open circuit voltage OCVₘᵢₙ, at the temperature T and current I considered. In this way, the maximum energy Eₘₐₓ may be deduced from the table 208 by finding in the latter, for the temperature T and the current I at their measurements T(t), I(t), the minimum open circuit voltage OCVₘᵢₙ and the associated total delivered energy Eₜₒₜ.

The computer program 132 also comprises a module 214 designed to estimate the state of energy SOE(t) of the cell 111 for the instant t, by subtracting the total energy delivered Eₜₒₜ(t) from the maximum energy Eₘₐₓ(t):

$$SOE ( t ) = {E}_{max} ( t ) - {E}_{tot} ( t ) \qquad [ Math . 5 ]$$

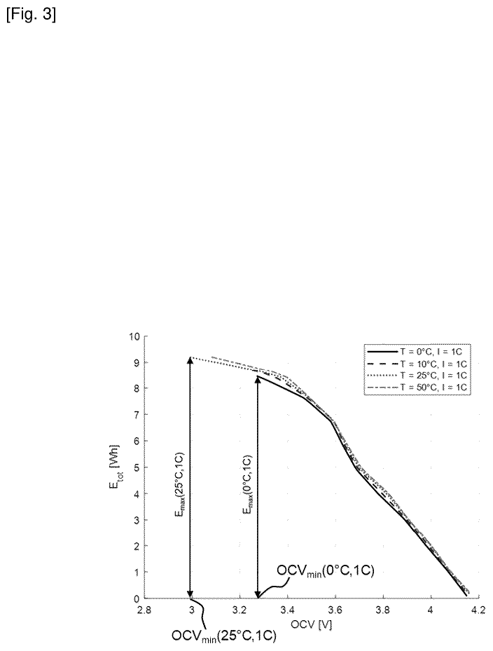

With reference to FIG. 3, examples of curves relating the total energy delivered Eₜₒₜ to the open circuit voltage OCV, for several combinations of temperature T and current I are illustrated. These curves therefore represent the data recorded in the table 208.

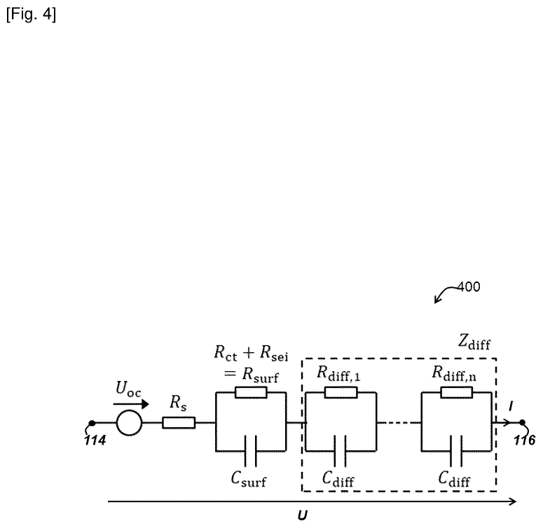

With reference to FIG. 4, an example of a model 400 of the cell 111 will now be described.

The model 400 comprises blocks connected in series between the two terminals 114, 116. The cell 111 presents the voltage U between these terminals 114, 116 and exchanges the current I via these terminals 114, 116.

A first block comprises a voltage source U_{oc} representing the open circuit voltage of the cell 111, i.e. the voltage that this cell 111 has when it is fully relaxed.

A second block comprises a series resistor Rₛ representing all the purely resistive contributions, such as the electrolyte, the current collectors and the contact resistors.

A third block comprises a resistor R_{surf} and a capacitor C_{surf} in parallel with each other, representing the surface resistance and capacitance linked to the voltage drop between the surface of the active material and the electrolyte due to charge transfer and the solid electrolyte interphase (SEI). The resistance R_{surf} and the capacitance C_{surf} thus define a time constant T_{surf}=R_{surf}C_{surf} linked to the surface phenomena (load transfer, SEI and double layer). This is a fast dynamic, normally less than one second.

n blocks (n greater than or equal to 1) each comprise a resistance R_{diff} and a capacitance C_{diff} representing diffusion phenomena of lithium ions in the electrolyte and lithium atoms in the two electrodes. The resistance R_{diff} and the capacitance C_{diff} of each of these n blocks defines a time constant T_{diff} =R_{diff}C_{diff} linked to the diffusion phenomena. This is a slow dynamic, lasting several seconds or minutes.

All these parameters depend on the state of charge SOC of the cell 111, the temperature T of the cell 111 and the current I in the cell 111, with the exception of the voltage source U_{oc} which does not depend on the current I. The model 400 therefore comprises, for example, a table for each of them, giving the value of the parameter in question as a function of the state of charge SOC, the temperature T and, where applicable, the current I.

In the model 400, the internal resistance R of the cell 111 is equal to the sum of the resistances Rs, Rsurf and Rdiff of the n blocks:

$$R = {R}_{s} + {R}_{surf} + {R}_{diff , 1} + … + {R}_{diff , n} \qquad [ Math . 3 ]$$

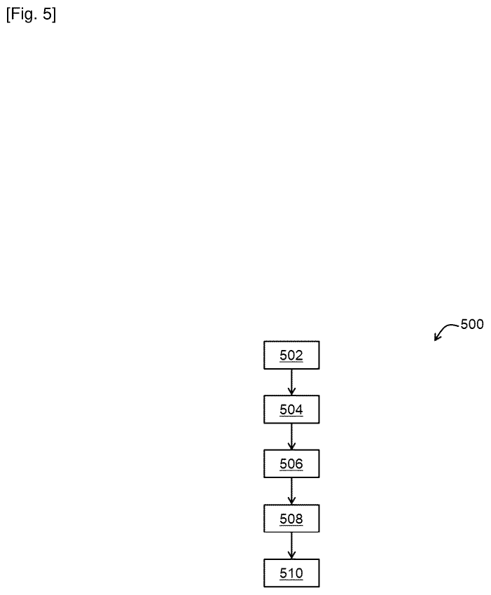

With reference to FIG. 5, an example of method (500) for determining the table 208 will now be described.

In a step 502, a temperature value T and current I are selected.

In a step 504, a complete discharge of the cell 111 is simulated using the model 400, keeping the temperature T and current I constant at their selected values.

In a step 506, an electrical energy supplied for the cell and a thermal energy dissipated by Joule effect over the simulation time are calculated from the simulation result. The total energy supplied Eₜₒₜ at each of several instants of the simulation is then calculated as the sum of the electrical energy supplied and the thermal energy dissipated at the instant of the simulation in question.

In a step 508, the open circuit voltage OCV is also calculated for each of the simulation instants, based on the simulation result.

In a step 510, for each of the simulation instants, the values of total energy delivered Eₜₒₜ and the associated open circuit voltage OCV are recorded in the table 208, along with the values of temperature T and current I.

The method 500 then returns to step 502 to select new values for temperature T and current I.

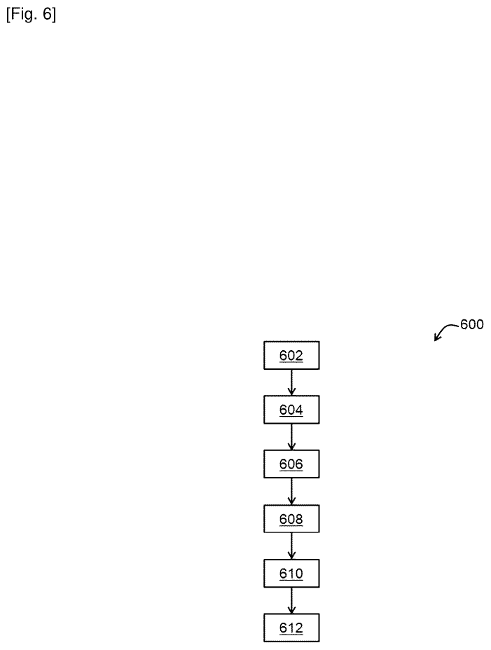

With reference to FIG. 6, an example of a method 600 for estimating the state of energy SOE(t) of the cell 111 at an instant t will now be described.

During a step 602, the module 202 receives the measurements T(t), U(t), I(t) of the temperature T, the voltage U and the current I, for the instant t.

In a step 604, the module 204 estimates the internal resistance R(t) of the cell 111 for the instant t.

During a step 606, the module 206 estimates the open circuit voltage OCV of the cell 111 for the instant t, from the measurement U(t) of the voltage U, the measurement I(t) of the current I and the estimation R(t) of the internal resistance R.

In a step 608, the module 210 estimates the total energy delivered Eₜₒₜ(t) by the cell 111 up to the instant t, from the measurement T(t) of the temperature T, the measurement I(t) of the current I and the estimation OCV(t) of the open circuit voltage OCV.

During a step 610, the module 212 estimates, for the instant t, the maximum energy Eₘₐₓ(t) that may be delivered by the cell 111, assuming that the temperature T and the current I remain constant.

In a step 612, the module 214 estimates, for the instant t, the state of energy SOE(t) of the cell 111, by subtracting the total delivered energy Eₜₒₜ(t) from the maximum energy Eₘₐₓ(t).

In conclusion, it should be noted that the invention is not limited to the embodiments described above. In fact, it will appear to the person skilled in the art that various modifications may be made to the above-described embodiments, in the light of the teaching just disclosed.

In the foregoing detailed presentation of the invention, the terms used should not be interpreted as limiting the invention to the embodiments exposed in the present description, but should be interpreted to include all equivalents the anticipation of which is within the reach of the person skilled in the art by applying his general knowledge to the implementation of the teaching just disclosed.

1. A method for estimating a state of energy of a cell of a battery for a given instant, the cell having two terminals, the method comprising:
receiving measurements for the given instant of a temperature of the cell, a voltage at the terminals of the cell, and a current exchanged by the cell across its terminals;
estimating an internal resistance of the cell for the given instant;
estimating an open circuit voltage of the cell for the given instant from the measured voltage and current, and from the estimated internal resistance;
estimating a total energy delivered by the cell up to the given from the measured temperature and current, and from the estimated open circuit voltage, using predefined associations between values of total energy delivered by the cell and values of temperature, current, and open circuit voltage;
estimating a maximum energy that may be delivered by the cell using the predefined associations and assuming that the temperature and the current remain constant at their measurements for the given instant; and
estimating the state of energy of the cell for the given instant by subtracting the estimated total delivered energy from the estimated maximum energy.

2. The method according to claim 1, wherein the internal resistance is estimated for the given instant on the basis of a volt-amperometric measurement.

3. The method according to claim 1, wherein the estimation of the internal resistance at the given instant comprises:
a prior estimation of the internal resistance for the given instant from the temperature and current measured at the given instant using predefined associations between values of the internal resistance and values of temperature and current; and
a correction of the prior estimation by multiplying the prior estimation by a correction ratio between:
an estimation of the internal resistance at a previous instant by a volt-amperometric measurement; and
an estimation of the internal resistance at the previous instant from the temperature and current measured at the previous instant, using the predefined associations between values of the internal resistance and values of temperature and current.

4. The method according to claim 1, wherein the estimation of the internal resistance at the given instant is carried out independently of a state of charge of the cell.

5. The method according to claim 1, wherein the predefined associations between values of total energy delivered by the cell and values of temperature, current, and open circuit voltage are in the form of a table.

6. The method according to claim 5, wherein the table gives the total energy delivered as a function of the open circuit voltage, at constant temperature and current, for several combinations of temperature and current.

7. The method according to claim 1, wherein the maximum energy is the total energy delivered for a minimum open circuit voltage provided by the predefined associations at the temperature and current measured at the given instant.

8. A computer program downloadable from a communications network and/or recorded on a computer-readable medium, comprising instructions for executing the steps of a method according to claim 1, when the program is executed on a computer.

9. A device for estimating a state of energy of a cell of a battery for a given instant, the cell having two terminals between which an electrical system is connected, the device comprising:
a module for receiving, for the given instant, measurements of a temperature of the cell, a voltage at the terminals of the cell, and a current exchanged by the cell across its terminals;
a module for estimating an internal resistance of the cell for the given instant;
a module for estimating an open circuit voltage of the cell for the given instant from the measured voltage and current, and from the estimated internal resistance;
a module for estimating a total energy delivered by the cell from the measured temperature and current, and from the estimated open circuit voltage, using predefined associations between values of total energy delivered by the cell and values of temperature, current, and open circuit voltage;
a module for estimating a maximum energy that may be delivered by the cell, assuming that the temperature and the current remain constant at their measurements for the given instant; and
a module for estimating the state of energy of the cell for the given instant by subtracting the estimated total delivered energy from the estimated maximum energy.

10. An aircraft, comprising:
a battery comprising at least one cell with two terminals;
a sensor for measuring a temperature of the cell;
a sensor for measuring a current exchanged by the cell across its terminals;
a sensor for measuring a voltage between the terminals of the cell; and
a device for estimating a state of energy of the cell according to claim 9.

11. The method according to claim 1, wherein the open circuit voltage is estimated by adding, to the measured voltage, a voltage of the internal resistance resulting from a passage of the measured current through the internal resistance.

12. The device according to claim 9, wherein the open circuit voltage is estimated by adding, to the measured voltage, a voltage of the internal resistance resulting from a passage of the measured current through the internal resistance.
